(19) United States
(12) Patent Application Publication
(10) Pub. No.: US 2007/0054419 A1
(43) Pub. Date: Mar. 8, 2007

(54) Wafer level chip size package for CMOS image sensor module and manufacturing method thereof

(76) Inventors: Kyung-Wook Paik, Yuseong-gu (KR); Myung-Jin Yim, Yuseong-gu (KR); Ho-Young Son, Yuseong-gu (KR)

Correspondence Address: BAKER & HOSTETLER LLP, WASHINGTON SQUARE, SUITE 1100, 1050 CONNECTICUT AVE. N.W., WASHINGTON, DC, 20036-5304, US

(21) Appl. No.: 11/513,203

(22) Filed: Aug. 31, 2006

(30) Foreign Application Priority Data
Sep. 2, 2005 (KR) 10-2005-0081887

(51) Int. Cl. H01L 21/00

(52) U.S. Cl. 438/1

(57) ABSTRACT

Disclosed is a wafer level chip size package for an image sensor module and a manufacturing method thereof, more particularly to a small size image sensor module characterized by a structure where a glass formed with an I/R cut-off filter (layer) is assembled onto an image sensor chip by a polymer partition wall and a solder bump is formed on an electrode of the rear side of a chip connected by a through-hole formed on each I/O electrode of an image sensor chip and a wafer level chip size package process for realizing the module. The method for manufacturing a wafer level chip size package for an image sensor module, the method comprises: bonding an image sensor wafer glass and a glass wafer to form a through-hole on the image sensor wafer; filling the through-hole formed on the image sensor wafer with an exciting material; and forming a solder bump at the end of the exciting material to be connected with the circuit formed PCB substrate. According to the present invention, the existing equipments for wafer processing and metal deposition are used. Therefore, it is possible to realize a cost-effective wafer level chip size package and an image sensor module having the minimum thickness in a thickness direction than the existing wafer level chip size package for image sensor and the same area as an image sensor chip.

### CROSS-REFERENCE TO RELATED APPLICATIONS

This application claims priority to Korean Patent Application No. 10-2005-0081887, filed Sep. 2, 2005, the disclosure of which is hereby incorporated by reference in its entirety.

### BACKGROUND OF THE INVENTION

1. Field of the Invention

The present invention relates to a wafer level chip size package for an image sensor module and a manufacturing method thereof, more particularly to a small size image sensor module characterized by a structure where a glass formed with an I/R cut-off filter (layer) is adhered onto an image sensor chip by a polymer partition wall and a solder bump is formed on an electrode of the rear side of a chip connected by a through-hole formed on each I/O (input/output) electrode of an image sensor chip and a wafer level chip size package process for realizing the module.

2. Background of the Related Art

For the past 20 years, a CCD (charge-coupled device) sensor monopolizes an image sensor market, but recently a CMOS (complementary metal oxide semiconductor) image sensor market grows remarkably to be predicted to exceed the CCD market in the amount and the sales. In particular, the use of CMOS image sensors drastically increases in the field of a mobile communication where a low power consumption characteristic is considered important, a specialized field where mutli-ability and a high integration are considered important and a high speed and a high pixel characterized fields etc. The major markets of the CMOS image sensors include a mobile phone, a digital still camera, an optical mouse, a surveillance camera and a biometrics.

A CMOS image sensor is manufactured into an image sensor module from a CMOS image sensor chip due to an electronic packaging technology to be mounted on various applications, and the package specifications required by the CMOS image sensor module depend on the characteristics of the final applications. Especially, the recent tendencies of CMOS image sensor modules such as a high electricity, a miniature/high density, a low power consumption, multifunctions, high speed signal processing and high reliability are representative characteristics of a small size package of the electronic appliances.

Contrary to general CMOS chips, the past CMOS image sensors are susceptical to the physical environment and can be polluted by impurities, and a Leadless Chip Carrier (LCC) typed package is used if the size does not matter. However, in a market such as a small form factor camera phone, chip-on-board (COB), chip-on-film (COF) and chip-size-package (CSP) are widely used.

In the chip-on-board method, a flexible PCB is assembled onto the rear side of an image sensor chip by a die attach and an input/output terminals of an image sensor are connected with the PCB electrode by a gold bonding wire. This method is disadvantageous in that the size of a module increases because a productivity increases but a space for wire bonding is required using a process similar to the existing semiconductor production line and the size increases in the thickness direction considering the height of the loop of a wire and IR lens.

In the chip-on-film method, the active side of an image sensor is directly bonded to an electrode of a flexible PCB or a flexible printed circuit. Therefore, a gold bonding wire is not required unlike a chip-on-board and the height to a lens barrel is lowered to manufacture a small size module. An anisotropic conductive film (ACF) is mainly used to interconnect an image sensor onto a flexible PCB or FPC, and a gold plating bump or an electroless nickel/gold bump is generally used as a bump formed on I/O terminals of an image sensor chip. Moreover, the flexible PCB or FPC is perforated as wide as a sensing area in order to transmit a light to a sensing area of an active side of an image sensor chip. FIGS. 1A and 1B are mimetic views of a chip-on-board and a chip-on-film method, respectively.

A chip size package technology is developed in order to realize a small size chip package of an image sensor module. As shown in FIG. 2, the chip size package CSP owned by ShellCase inc. of Israel is mounted with an image sensor chip on a substrate glass and has an empty space between the image sensing area and an upper glass. In the case, an epoxy resin is bonded around the space and an electric wiring is formed from the I/O of an image sensor chip on the rear side of the substrate glass, resulting in forming a solder ball, finally. This chip size package is capable of carrying out a wafer level process in order to simplify a module manufacturing and advantageous in decreasing the area of a module. However, the upper glass substrate and the lower glass substrate are used, respectively, therefore it is insufficient to further decrease the height of an image sensor module.

Recently, a glass for an I/R filter incorporated with a substrate is developed into a package by a chip-on-glass (COG) method in a trial for decreasing the size of a module of an image sensor, as shown in FIG. 3.

In other words, an image sensor chip formed with a solder bump on an I/O forms an electrode and a wiring on a wafer-typed glass substrate and is bonded by a solder ball for the second connection. An image sensor chip is flip-chip bonded and then a glass substrate mounted with an image sensor chip is diced to manufacture an image sensor module. This method is advantageous in that the thickness of an image sensor module can be minimized, but is disadvantageous in that the width increases, because the size of a glass substrate is wider than an image sensor chip. As an individual chip is assembled on a glass wafer, this cannot be called a wafer level package in a strict sense.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIGS. 1A and 1B are perspective views showing the structure of an image sensor module in a form of a Chip-on-Board (COB) and a Chip-on-Film (COF) of an image sensor.

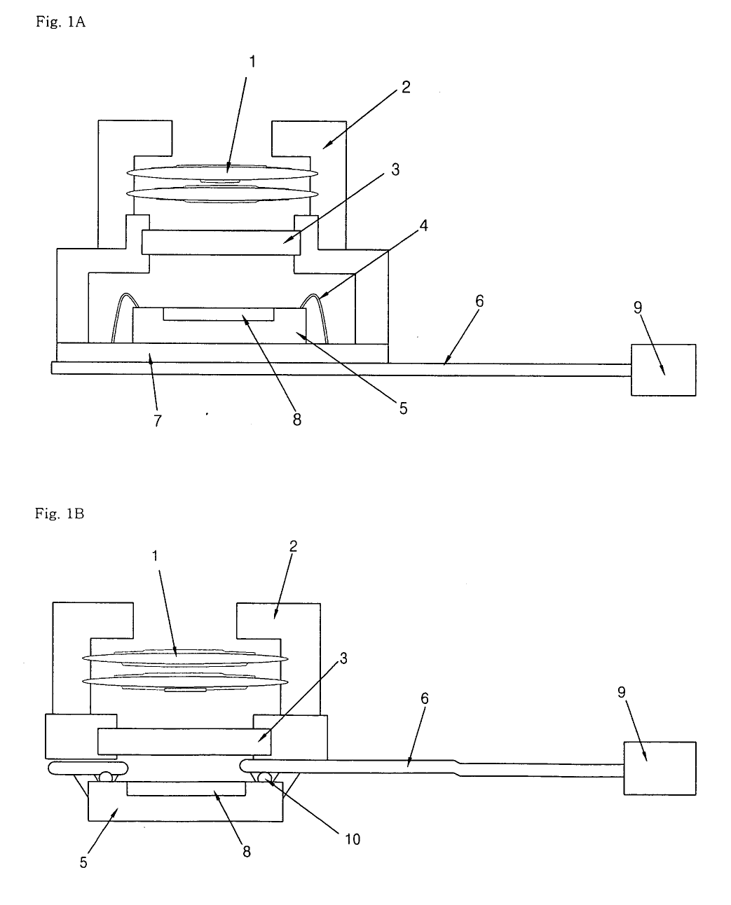

FIG. 2 is a perspective view showing the structure of a chip-size package (CSP) for the image sensor module.

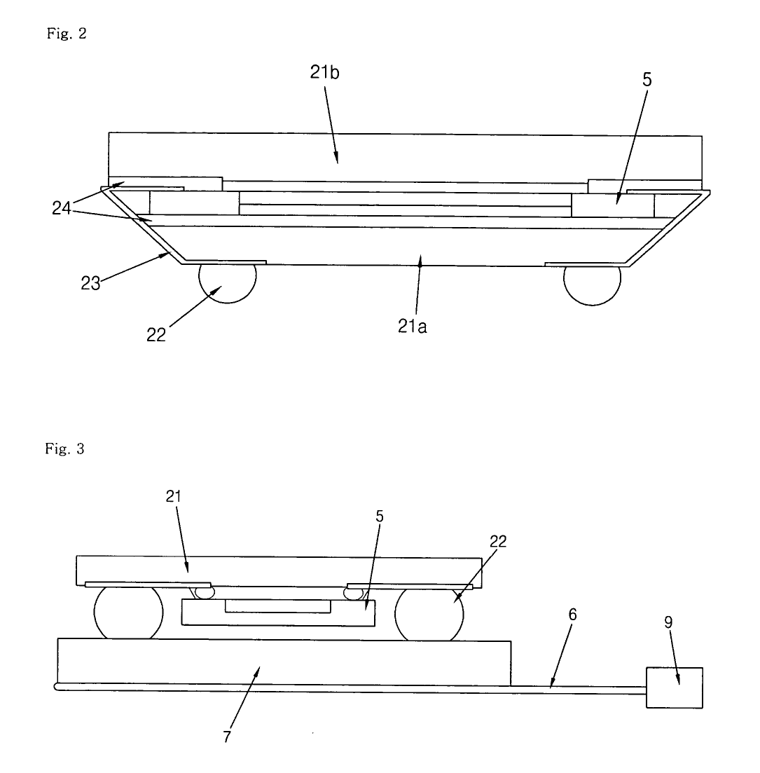

FIG. 3 is a perspective view showing the structure of a chip-on-glass (COG) type image sensor module.

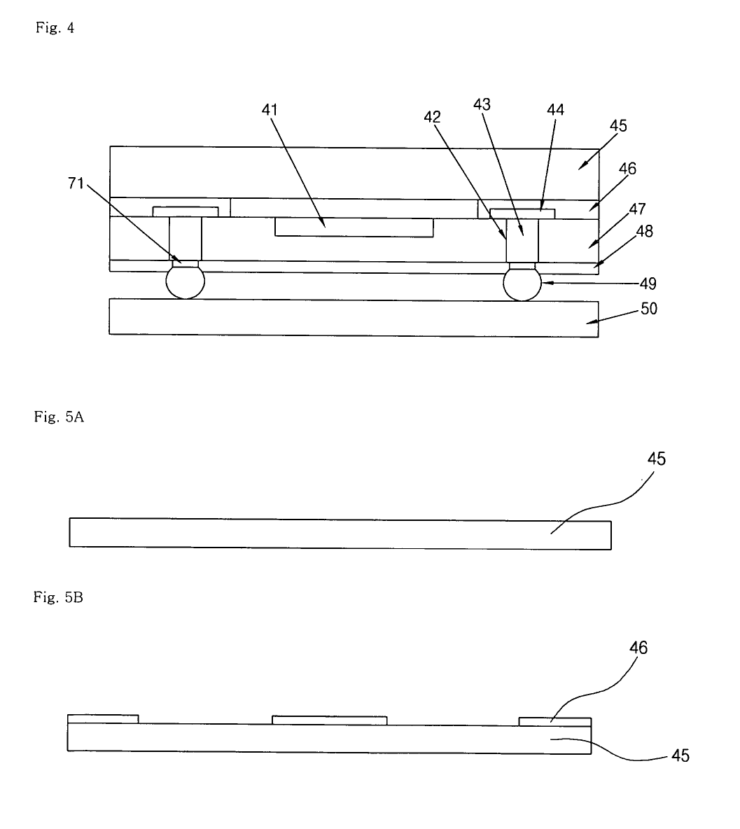

FIG. 4 is a cross-sectional view of an image sensor module using a wafer level chip size package (WL-CSP) technology in accordance with an embodiment of the present invention.

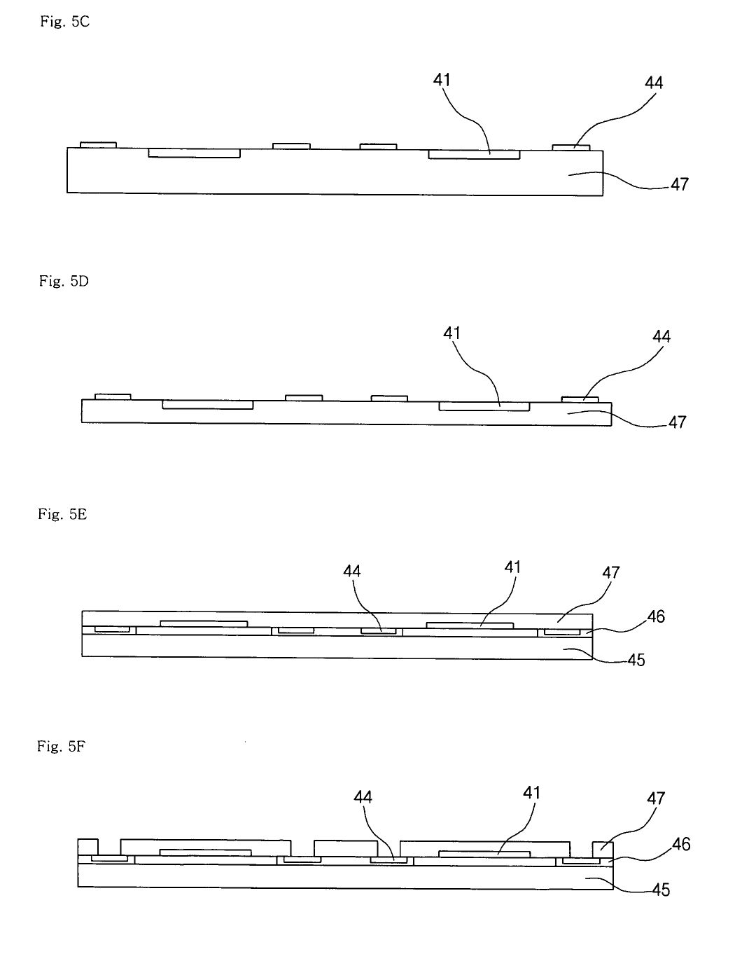

FIGS. 5A to 5F show a bonding process between an image sensor wafer and a glass wafer coated with an I/R cut-off filter for realizing a wafer level chip size package for an image sensor module in accordance with an embodiment of the present invention.

FIGS. 6A to 6E show a process for coating a through-hole formed from each I/O electrode to the rear side of a wafer with an SiO₂ insulating layer and a process of interconnection for filling the through-hole with a conductive material.

FIGS. 7A to 7D show a process for forming a bump for realizing a wafer level chip size package (WL-CSP) for an image sensor module in accordance with an embodiment of the present invention and an assembly process thereof.

### SUMMARY OF THE INVENTION

In order to solve the above-identified problem, an object of the present invention is to provide a wafer level chip size package capable of realizing a small size image sensor module and a method thereof.

In order to obtain the objects, a method for manufacturing a wafer level chip size package for an image sensor module, the method comprises: bonding an image sensor wafer glass and a glass wafer to form a through-hole on the image sensor wafer; filling the through-hole formed on the image sensor wafer with an exciting material; and forming a solder bump at the end of the exciting material to be interconnected with the circuit formed PCB substrate.

According to the present invention, the step for bonding the image sensor wafer and the glass wafer to form a through-hole on the image sensor wafer, preferably comprises; preparing a glass wafer coated with an I/R cut-off filter; forming a polymer partition wall on a side opposite to the I/R cut-off filter; preparing an image sensor wafer; grinding an image sensor wafer to decrease a thickness of the image sensor wafer; bonding the glass wafer and the image sensor wafer; and forming a through-hole on a rear side of the image sensor wafer.

According to the present invention, it is preferable that the size of a glass wafer coated with the LIR cut-off filter be made by an even inch.

According to the present invention, it is preferably that the polymer partition wall be formed of at least one selected from the group consisting of polyimide, benzocyclobutene and photosensitive agent being a photosensitive polymer material.

According to the present invention, preferably, the polymer partition wall has a lattice structure and has the thickness of 5˜20 μm.

According to the present invention, it is preferable that the image sensor wafer have the same size as the glass wafer.

According to the present invention, it is preferable that the image sensor wafer be grinded to have the thickness of 100˜200 μm.

According to the present invention, it is preferable that the glass wafer and the image sensor wafer be bonded by a wafer thermal compression process.

According to the present invention, it is preferable that the through-hole is formed by either Deep Reactive Ion Etching (RIE) method or a laser drilling.

According to the present invention, it is preferable that the radius of the through-hole be 100˜200 μm.

According to the present invention, it is preferable that the step of filling the through-hole formed on the image sensor wafer with an exciting material comprise: forming an insulating layer at the other portions except a metal pad; forming a seed metal layer on the image sensor wafer surface and a through-hole; carrying out a filling process using a metal material on the upper portion of the seed metal layer; grinding the metal material to planarize the rear side of the image sensor so that the metal material remains only in the through-hole; and forming a polymer insulating layer at the other portions except the portions formed in the through-hole of the rear side of the image sensor wafer.

According to the present invention, it is preferable that the insulating layer employ a SiO₂.

According to the present invention, it is preferable that the insulating layer be formed using a chemical vapor deposition method.

According to the present invention, it is preferable that the seed layer be formed using Ti/Cu sputtering or deposition method.

According to the present invention, it is preferable that the thickness of the image sensor wafer after the planarization process become 50˜150 μm.

According to the present invention, it is preferable that the through-hole be filled with at least one metal material selected from the group consisting of Cu, Ag, Ni and Au.

According to the present invention, it is preferable that the step for forming a solder bump at an end of the exciting material to be connected with a Printed Circuit Board comprise: forming an under bump metal at an end of the through-hole to form a solder ball on the upper metal of the under bump; and connecting the image sensor module formed with the solder ball to a Printed Circuit Board.

According to the present invention, it is preferable that the under bump metal be an electroless Ni/Au plating layer.

According to the present invention, a wafer level chip size package for an image sensor module comprises: a glass wafer coated with an I/R cut-off filter; and a Printed Circuit Board formed with a through-hole filled with a metal material for I/Os of signals and a solder bump at an end of the metal material to be connected with a circuit so as to be electrically connected to an image sensor wafer and the solder bump.

### DETAILED DESCRIPTION OF THE INVENTION

Hereinafter, embodiments of the present invention will be described in detail with reference to the attached drawings. Reference now should be made to the drawings, in which the same reference numerals are used throughout the different drawings to designate the same or similar components. In the following description of the present invention, detailed descriptions may be omitted if it is determined that the detailed descriptions of related well-known functions and construction may make the gist of the present invention unclear.

Bonding Process between an Image Sensor Wafer and a Glass Wafer

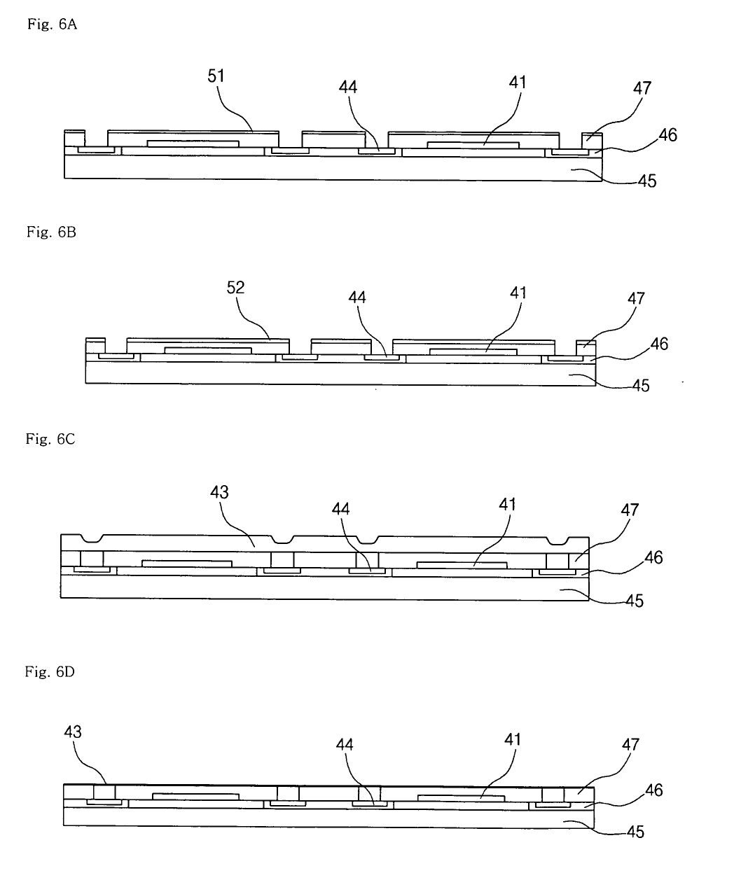

FIGS. 5A to 5F show a bonding process between an image sensor wafer and a glass wafer coated with an I/R cut-off filter.

FIG. 5A shows a step for preparing a glass wafer (45) coated with an LIR cut-off filter, the size of which may be 4, 6, 8 and 10 inches.

FIG. 5B shows a step for forming a polymer partition wall (46) having a lattice structure on a surface opposite to the glass wafer (45) coated with an I/R cut-off filter. This step is for constituting the wafer level chip size package for an image sensor module and realizing a receptacle, in other words, a kind of a semi-hermetic package which protects an image sensing region. A representative photosensitive polymer material or Benzocyclobutene is used in order to form a polymer partition wall (46) with a lattice structure on the opposite side to the glass wafer (45) coated with an IR cut-off filter. In other words, BCB material is coated on the glass wafer (45) using a spin coating process and a polymer partition wall (46) structure with a lattice structure is formed using a mask and a lithography process. The image sensor chip wafer is bonded to a BCB polymer layer to expose an image sensing region of an image sensor chip. The height of the polymer partition wall is about 5 to 20 μm. After the spin coating of BCB layer, the lithography process is adopted for making a BCB polymer lattice structure and not for hardening the BCB polymer lattice structure layer prior to a bonding process between the succeeding wafers.

FIG. 5C shows a process for preparing an image sensor wafer (47) having the same size as the glass wafer (45) coated with an IR cut-off filter (layer) in the step for preparing an image sensor wafer.

FIG. 5D shows a step for grinding the rear side of the image sensor wafer (47) so that the wafer has a thickness of 100 to 200 μm.

FIG. 5E shows a process for carrying out a wafer bonding by hardening the polymer partition wall (46) such that an image sensing area on the image sensor chip wafer (47) is aligned with the polymer partition wall (46) with a lattice structure formed on a rear side of the glass (45) coated with an I/R cut-off filter surface in a process for bonding the glass wafer (45) on which the polymer partition wall (46) is formed to the image sensor wafer (47). At this time, the interfacial process between two wafers are carried out by a wafer thermocompression process and the bonding strength depends on hardening of the polymer partition wall (46) with a lattice structure formed on the image sensor chip wafer (47) and a process pressure when bonding wafers. At this time, the polymer partition wall (46) with a lattice structure which playing a bonding layer between the image sensor chip wafer (47) and the glass wafer (45) play as an adhesion layer between the image sensor chip wafer (47) and a semi-hermetic sealing between a sensor chip and a glass substrate in an individual sensor module after a dicing is completed.

The foregoing polymer partition wall structure (46) layer such as BCB formed on the glass wafer (45) is thermally pressed for a certain period by heat and pressure using a kind of hot bar to be thermally compressed with a front surface of an image sensor wafer (47) by post curing it, finally.

At this time, the polymer partition wall (46) is thermally compressed between wafers while being hardened completely. The thermal compression process between wafers should be optimized so that voids are not present within a polymer partition wall and the adhesion between wafers maintains to be uniform. In addition, the polymer partition wall (46) layer has a perfect sealing and a high adhesion strength between wafers. The pattern size of a polymer partition wall (46) increases more or less due to temperature and pressure applied to the glass wafer (45) such that a possible initial pattern is maintained itself.

FIG. 5F is a step for forming a through-hole from a backside of the image sensor wafer (47) to each I/O electrode, where a through-hole with a little larger than each I/O size is formed at the arrangement position of each I/O of the image sensor chip (47) using a Deep RIE (Deep Reactive Ion Etching) or a laser drilling method. The silicon wafer etching by the Deep RIE method is advantageous in that a through-hole having a processing surface which is soft and close to perpendicularity comparing to a laser drilling method. The Deep RIE method is to mix a gas such as SF₄, SF₆ and CF₄ including fluorine (F) with an oxygen gas to form SiF₄ via a reaction of the dissolved fluorine gas (F₂) and silicon (Si) for etching a silicon wafer. A portion to be etched on a silicon wafer is selected using a hard mask like a metal mask and a soft mask like a photo mask. In other words, after the photo mask is patterned through an exposure, the region where the photo resist is formed is not etched because a fluorine gas does not contact, while the portion where the photo resist is opened is etched because a fluorine gas is reacted with a silicon wafer. If the soft mask like a photo resist is removed, a through-hole with the thickness of about 100 to 200 μm can be formed. This method is advantageous in forming a through-hole with a relatively large aspect ratio of 1:10 or higher to obtain a desired thickness of the I/O size and an image sensor silicon wafer.

Process for Mutual Combination for Filling a Through-Hole Formed on an Image Sensor Wafer with an Exciting Material

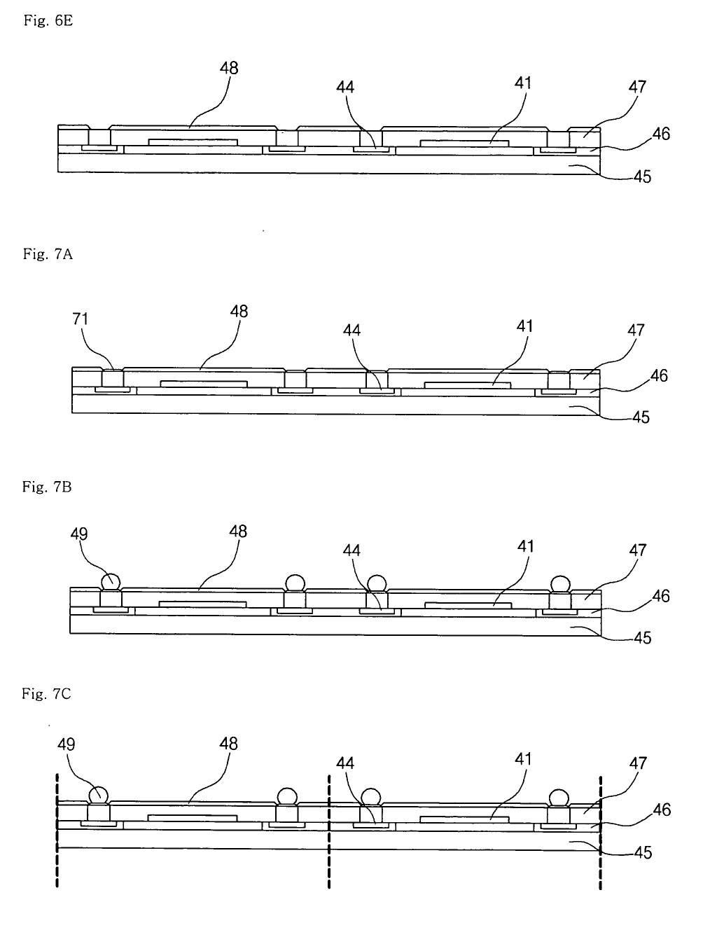

FIGS. 6A to 6E show a process for filling a through-hole formed on a glass wafer connected to an image sensor chip wafer with a metal material using an electrical metal plating method. In order to form an insulating layer SiO₂ (51) on a wall of a hole, SiO₂ (51) is selectively coated on just Si surface using SiO₂ CVD (Chemical Vapor Deposition) method, after a through-hole is formed. (FIG. 6A) At this time, A1 pad of a chip should not be coated with SiO₂. A seed metal layer (52) is formed on an image sensor wafer surface where a through-hole is formed for an electrical metal plating and inside a through-hole. (FIG. 6B) At this time, a Ti/Cu sputtering process is used for depositing the seed metal layer (52). Next, a process for filling a through-hole with a metal material (43) is carried out using an electrical plating method. (FIG. 6C) At this time, the through-holes are filled with Cu and all the regions coated with the seed metal layer (52) are coated by Cu plating. Next, the surface coated with Cu is grinded to expose all rear sides of an image sensor wafer, and a planarization process is performed so that the rear side of an image sensor wafer and through-holes have the equivalent height after wafer planarization process. (FIG. 6D) Therefore, the thickness of an image sensor wafer becomes 50 to 150 μm. Next, a polymer insulating layer is coated on the entire rear side of the image sensor wafer and a patterning process for exposing a through-hole electrode is performed by a lithography process (FIG. 6E). Finally, an electrical signal from an image sensor chip is transmitted from each I/O of an image sensor wafer to the outside via a through-hole filled with Cu.

Process for forming a solder ball on a through-hole surface filled with a metal material on an image sensor chip wafer and assembling on a PCB substrate.

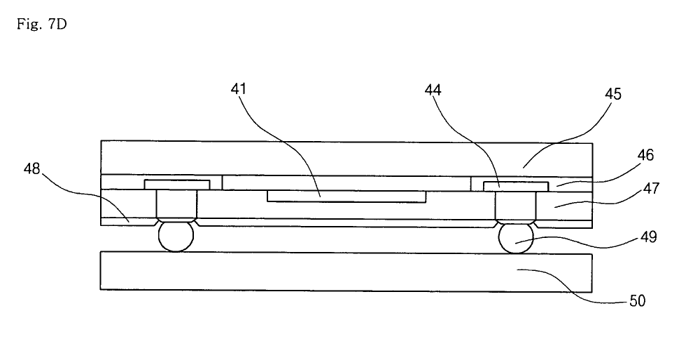

FIGS. 7A to 7D show an under bump metal (UBMs) (signals are not shown) for forming a solder ball for electrical connection with the second substrate on a through-hole filled with a metal material formed on a rear side of an image sensor chip wafer. (FIG. 7A) For example, an electroless Ni/Au plating layer is formed to play a role as UBMs. Next, solder pastes are covered on an electrode of a rear side of an image sensor wafer (46) by a screen printing method and a reflow is performed. Next, the remaining flux is removed by a solvent and the solder ball (49) is formed on each UBM. (FIG. 7B)

The attached image sensor chip wafer and the glass wafer are diced into individual image sensor modules. (FIG. 7C) Using general dicing equipments, a blade capable of effectively cutting a silicon and a glass is selected and the optimal dicing progress conditions are selected. The last step is a chip-on-board process for connecting an image sensor module to which a solder ball is attached is connected to a flexible or organic PCB substrate using a solder reflow. In other words, the chip-on-board process is completed by a solder reflow between a solder ball formed on an electrode of a through-hole of an image sensor chip and a PCB substrate electrode. An electrode of a PCB substrate has an electrode structure where 5˜8 μm nickel/0.2 μm gold is formed on a copper wiring with the thickness of 18 μm. An underfill process can be added if required for improving the reliability.

The forgoing embodiments are merely exemplary and are not to be construed as limiting the present invention. The description of the present invention is intended to be illustrative, and not to limit the scope of the claims. Many alternatives, modifications and variations will be apparent to those skilled in the art.

As described above, according to the present invention, the existing equipments for wafer processing and metal deposition are used. Therefore, it is possible to realize a cost-effective wafer level chip size package and an image sensor module having the minimum thickness in a thickness direction than the existing wafer level chip size package for image sensor and the same area as an image sensor chip.

In addition, as an electrical signal which outputs from I/O of an image sensor flows to the outside via a through-hole formed in a thickness direction of a thin image sensor chip, it is possible to realize an image sensor module with high electric signal characteristics, thermal transmittance characteristics and a high mechanical reliability.

As a smaller number of processes and materials are used than the existing wafer level chip size package, it is possible to obtain a cost-effective and highly reliable image sensor module package. Moreover, the present invention has technical effects on realizing a small form factor sensor chip package besides an image sensor package.

What is claimed is:

1. A method for manufacturing a wafer level chip size package for an image sensor module, the method comprising:
bonding an image sensor wafer glass and a glass wafer to form a through-hole on the image sensor wafer;
filling the through-hole formed on the image sensor wafer with an exciting material; and
forming a solder bump at the end of the exciting material to be connected with the circuit formed PCB substrate.

2. The method of claim 1, wherein the step for bonding the image sensor wafer and the glass wafer to form a through-hole on the image sensor wafer comprises;
preparing a glass wafer coated with an I/R cut-off filter;
forming a polymer partition wall on a side opposite to the I/R cut-off filter;
preparing an image sensor wafer;
grinding an image sensor wafer to decrease a thickness of the image sensor wafer;
bonding the glass wafer and the image sensor wafer; and
forming a through-hole on a rear side of the image sensor wafer.

3. The method of claim 2, wherein the size of a glass wafer coated with the I/R cut-off filter is made by an even inch.

4. The method of claim 2, wherein the polymer partition wall is formed of at least one selected from the group consisting of polyimide, benzocyclobutene and photosensitive agent being a photosensitive polymer material.

5. The method of claim 2, wherein the polymer partition wall has a lattice structure.

6. The method of claim 2, wherein the polymer partition wall has the thickness of 5˜20 μm.

7. The method of claim 2, wherein the image sensor wafer has the same size as the glass wafer.

8. The method of claim 2, wherein the image sensor wafer is grinded to have the thickness of 100˜200 μm.

9. The method of claim 2, wherein the glass wafer and the image sensor wafer is bonded by a wafer thermal compression process.

10. The method of claim 2, wherein the through-hole is formed by either Deep Reactive Ion Etching (RIE) method or a laser drilling.

11. The method of claim 2, wherein the radius of the through-hole is 100˜200 μm.

12. The method of claim 1, wherein the step of filling the through-hole formed on the image sensor wafer with an exciting material comprises:
forming an insulating layer at the other portions except a metal pad;
forming a seed metal layer on the image sensor wafer surface and a through-hole;
carrying out a filling process using a metal material on the upper portion of the seed metal layer;
grinding the metal material to planarize the rear side of the image sensor so that the metal material remains only in the through-hole; and
forming a polymer insulating layer at the other portions except the portions formed in the through-hole of the rear side of the image sensor wafer.

13. The method of claim 12, wherein the insulating layer employs a SiO₂.

14. The method of claim 12, wherein the insulating layer is formed using a chemical vapor deposition method.

15. The method of claim 12, wherein the seed layer is formed using a Ti/Cu sputtering or deposition method.

16. The method of claim 12, wherein the thickness of the image sensor wafer becomes 50˜150 μm after the planarization process is completed.

17. The method of claim 12, wherein the through-hole is filled with at least one metal material selected from the group consisting of Cu, Ag, Ni and Au.

18. The method of claim 1, wherein the step for forming a solder bump at an end of the exciting material to be connected with a Printed Circuit Board comprises:
forming an under bump metal at an end of the through-hole to form a solder ball on the upper metal of the under bump; and
connecting the image sensor module formed with the solder ball to a Printed Circuit Board.

19. The method of claim 18, wherein the under bump metal is an electroless Ni/Au plating layer.

20. A wafer level chip size package for an image sensor module comprises:
a glass wafer coated with an I/R cut-off filter; and
a Printed Circuit Board formed with a through-hole filled with a metal material for I/Os of signals and a solder bump at an end of the metal material to be connected with a circuit so as to be electrically connected to an image sensor wafer and the solder bump.

21. The package of claim 20, further comprising a polymer partition wall between the glass wafer and the image sensor wafer for bonding.

22. The package of claim 20, further comprising a metal pad at an upper portion of the through-hole for connecting electric signals with an image sensor chip.

23. The package of claim 20, wherein the metal material is at least one material selected from the group consisting of Cu, Ag, Ni and Au.

24. The package of claim 20, further comprising an under bump metal for connecting with a solder ball at a lower portion of the through-hole.

25. The package of claim 24, wherein the under bump metal is an electroless Ni/Au plating layer.

26. The package of claim 20, wherein the wafer surface of an image sensor formed with the solder bump comprises an electroless insulating layer at other portions except the portion where the solder bump is formed.
